(19) United States
(12) Patent Application Publication
(10) Pub. No.: US 2025/0024699 A1
(43) Pub. Date: Jan. 16, 2025

(54) PHOTOELECTRIC DEVICE AND PREPARATION METHOD THEREFOR, AND DISPLAY APPARATUS

(71) Applicant: TCL TECHNOLOGY GROUP CORPORATION, Huizhou, Guangdong (CN)

(72) Inventor: Jing WANG, Huizhou, Guangdong (CN)

(73) Assignee: TCL TECHNOLOGY GROUP CORPORATION, Huizhou, Guangdong (CN)

(21) Appl. No.: 18/707,581

(22) PCT Filed: Oct. 26, 2022
(86) PCT No.: PCT/CN2022/127684

§ 371 Date: May 4, 2024

(30) Foreign Application Priority Data
Nov. 4, 2021 (CN) 202111302002.2

(51) Int. Cl. H10K 50/18; H10K 71/12; H10K 85/10; H10K 85/40

(52) U.S. Cl. CPC H10K 50/181; H10K 71/12; H10K 85/1135; H10K 85/40

(57) ABSTRACT

The present disclosure provides a photoelectric device and preparation method therefor, and display apparatus. The photoelectric device includes an anode, a light-emitting layer, an electronic function layer, and a cathode disposed in stack, wherein a material of the electronic function layer includes a two-dimensional montmorillonite nanosheet with anisotropic conductivity such that the electronic functional layer has a large band gap perpendicular to a film layer and a good conductivity along a surface direction of the film layer, thereby improving charge injection balance and luminescence uniformity of the photoelectric device.

The present disclosure claims priority to Chinese Patent Application No. 202111302002.2, filed on Nov. 4, 2021, and entitled “PHOTOELECTRIC DEVICE AND PREPARATION METHOD THEREFOR, AND DISPLAY APPARATUS”, the disclosure of which is incorporated herein by reference in its entirety.

### TECHNICAL FIELD

The present disclosure relates to the technical field of display technology, and in particular, to a photoelectric device and preparation method therefor, and display apparatus.

### BACKGROUND

QLED(Quantum-Dot Light Emitting Diode) is an electroluminescent diode based on quantum dot technology. It has a series of excellent characteristics such as self-illumination, no backlight module, wide viewing angle, high contrast, full solidification, suitable for flexible panels, good temperature characteristics, fast response speed, energy saving and environmental protection, and has become a research hotspot and key development direction of new display technologies. QLED is a thin film laminated device structure. The QLED is usually formed of an anode, a hole injection layer, a hole transport layer, a light-emitting layer, an electron transport layer, an electron injection layer, and a cathode. Among them, commonly utilized materials such as materials of hole injection layer, hole transport layer, light-emitting layer, electron transport layer are organic small molecule materials or inorganic nano-materials which are very suitable for deposition of thin films by solution methods. Therefore, based on factors such as flexibility, large size, and cost reduction, solution methods such as inkjet printing are gradually becoming new manufacturing technologies for mass production and development of QLED display technology.

However, there are many problems to be solved urgently in the preparation of QLED by solution methods, typical problems are the consistency of device performance, the stability of device aging and so on. The consistency of device performance is mainly manifested as uneven luminescence, and the uneven luminescence is essentially due to factors such as the uneven thickness of a film, the surface defects (pinholes, agglomerations, etc.), the stress release of a film, the degree of adhesion among multiple films, and the uniformity of materials. The conductivity of each region of the film is different, that is, the current preferentially passes through a region with low in-plane resistance of the film, resulting in the luminescence of the region is higher than other regions. At present, technology development mainly focuses on improving the quality of the film formation through the improvement of material stability and the optimization of ink process, thereby improving the uniformity of device luminescence. With regard to device aging stability, from the perspective of QLED devices themselves, many studies have concluded that the degradation of a device's lifespan is primarily attributed to factors such as the deterioration of the hole functional layer, the accumulation of interfacial charges, the inhibition of defect states on the surface of the electron functional layer or the change in charge mobility. Charge injection imbalance is one of multiple important reasons for the above factors.

### Technical Problem

Uneven luminescence and charge injection imbalance affect performance consistency and aging stability of a device.

### Technical Solutions

Accordingly, the present disclosure provides a photoelectric device and preparation method therefor, and display apparatus.

An embodiment of the present disclosure provides a photoelectric device including an anode, a light-emitting layer, an electronic function layer, and a cathode disposed in stack; wherein a material of the electronic function layer comprises a two-dimensional montmorillonite nanosheet.

Optionally, in some embodiments, the material of the electronic function layer is the two-dimensional montmorillonite nanosheet.

Optionally, in some embodiments, the two-dimensional montmorillonite nanosheet is selected from one or more of a calcium-based two-dimensional montmorillonite nanosheet, a sodium-based two-dimensional montmorillonite nanosheet, a sodium-calcium-based two-dimensional montmorillonite nanosheet, and a magnesium-based two-dimensional montmorillonite nanosheet.

Optionally, in some embodiments, the two-dimensional montmorillonite nanosheet include two-dimensional montmorillonite nanosheet obtained by an inorganic modification or an organic modification; wherein the inorganic modification comprises using one or more of an inorganic acid and an inorganic salt to modify; the organic modification comprises using one or more of an organic acid, a surfactant, a polymer monomer, and a coupling agent to modify.

Optionally, in some embodiments, the inorganic acid is selected from one or more of sulfuric acid, hydrochloric acid, nitric acid, and phosphoric acid; the organic acid is selected from one or more of a carboxylic acid, a sulfonic acid, a sulfinic acid, and a thiocarboxylic acid; the inorganic salt is selected from one or more of aluminum, magnesium, zinc, copper, sodium a halogen salt, a nitrate, a sulfate, a phosphate, a carboxylate salt, a sulfonate, a sulfinate, or a thiocarboxylate salt; the surfactant is selected from one or more of a cationic surfactant, an anionic surfactant, and a nonionic surfactants;

The polymer monomers is selected from one or more of methyl methacrylate, N-vinyl pyrrolidone, pyrrole, ethylene terephthalate, and ethylene naphthalate; the coupling agent is selected from one or more of a silane coupling agent, a titanate coupling agent, and a polyurethane coupling agent.

Optionally, in some embodiments, the material of the electronic function layer includes a composite of the two-dimensional montmorillonite nanosheet and a polymer; the polymer is selected from one or more of PMMA, PI, PAI, and PE.

Optionally, in some embodiments, in the composite, a mass ratio of the polymer to the two-dimensional montmorillonite nanosheet is greater than 0:1 and less than or equal to 5:1.

Optionally, in some embodiments, the anode is selected from one or more of a metal electrode, a silicon carbon electrode, a doped or non-doped metal oxide electrode, and a composite electrode; wherein a material of the metal electrode is selected from one or more of Al, Ag, Cu, Mo, Au, Ba, and Ca; a material of the silicon carbon electrode is selected from one or more of silicon, graphite, carbon nanotube, graphene and carbon fiber; a material of the doped or non-doped metal oxide electrode is selected from one or more of AZO, GZO, IZO, and AMO; a material of the composite electrode is selected from one or more of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, TiO₂/Ag/TiO₂, and TiO₂/Al/TiO₂; the cathode is selected from one or more of a metal electrode, a silicon carbon electrode, a doped or non-doped metal oxide electrode, and a composite electrode; wherein a material of the metal electrode is selected from one or more of Al, Ag, Cu, Mo, Au, Ba, and Ca; a material of the silicon carbon electrode is selected from one or more of silicon, graphite, carbon nanotube, graphene and carbon fiber; a material of the doped or non-doped metal oxide electrode is selected from one or more of ITO, FTO, ATO, AZO, GZO, IZO, MZO, and AMO; a material of the composite electrode is selected from one or more of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, TiO₂/Ag/TiO₂, and TiO₂/Al/TiO₂; a material of the light-emitting layer is selected from one or more of a quantum dot with single structure, a quantum dot with a core-shell structure, and a perovskite semiconductor material; the single structure quantum dot is selected from one or more of a group II-VI compound, a group IV-VI compound, a group III-V compound, a group I-III-VI compound; the group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe; the group IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe; the group III-V compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb; the group I-III-VI compound is selected from one or more of CuInS₂, CuInSe₂, and AgInS₂; a core of the quantum dot with a core-shell structure is selected from any one of the single structure quantum dots; a shell material of the quantum dot with a core-shell structure is selected from one or more of CdS, CdTe, CdSeTe, CdZnSe, CdZnS, CdSeS, ZnSe, ZnSeS, and ZnS; the perovskite semiconductor material is selected from a doped or non-doped inorganic perovskite type semiconductor, an organic perovskite semiconductor or an organic-inorganic hybrid perovskite type semiconductor; the inorganic perovskite type semiconductor has a general structural formula of AMX₃, wherein A is Cs⁺, and M is a divalent metal cation which is selected from one or more of Pb²⁺, Sn²⁺, Cu²⁺, Ni²⁺, Cd²⁺, Cr²⁺, Mn²⁺, Co²⁺, Fe, G²⁺, GYb²⁺, and Eu²⁺, and X is a halogen anion which is selected from one or more of Cl⁻, Br⁻, and I⁻; the organic-inorganic hybrid perovskite type semiconductor has a general structural formula of CMX₃, wherein C is a formamidyl, and M is a divalent metal cation which is selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, and X is a halogen anion which is selected from one or more of Cl⁻, Br⁻, and I⁻; the organic-inorganic hybrid perovskite type semiconductor has a general structural formula of BMX₃, wherein B is an Organic amine cation which is selected from one or more of CH₃(CH₂)ₙ₋₂NH₃⁺ or [NH₃(CH₂)ₙNH₃]²⁺, wherein n−2, and M is a divalent metal cation which is selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, and X is a halogen anion which is selected from one or more of Cl⁻, Br⁻, and I.

Optionally, in some embodiments, the photoelectric device further includes a hole transport layer disposed between the anode and the light-emitting layer; the photoelectric device further includes a hole injection layer disposed on a surface of the anode facing one side of the cathode.

Optionally, in some embodiments, the photoelectric device further includes an electron transport layer disposed between the light-emitting layer and the cathode.

Optionally, in some embodiments, the photoelectric device further includes an electron injection layer disposed on a surface of the cathode facing one side of the anode.

Optionally, in some embodiments, a thickness of the electronic functional layer is 1 nm to 50 nm.

Correspondingly, the embodiment of the present disclosure also provide a preparation method for a photoelectric device including: providing a first electrode; forming a light-emitting layer on the first electrod; forming a second electrode on the light-emitting layer; and the method further includes: obtaining an electronic functional layer by using a solution including the two-dimensional montmorillonite nanosheet with a solution method, wherein the electronic functional layer and the light-emitting layer are disposed between the first electrode and the second electrode.

Optionally, in some embodiments, the first electrode is an anode, and the second electrode is a cathode, and prior to forming the second electrode, the obtaining an electronic functional layer by using a solution including the two-dimensional montmorillonite nanosheet with a solution method comprises disposing the solution including the two-dimensional montmorillonite nanosheet on the light-emitting layer by the solution method.

Optionally, in some embodiments, the first electrode is a cathode, and the second electrode is an anode, and prior to forming the light-emitting layer, the obtaining an electronic functional layer by using a solution including the two-dimensional montmorillonite nanosheet with a solution method comprises disposing the solution including the two-dimensional montmorillonite nanosheet on the first electrode by the solution method.

Optionally, in some embodiments, the two-dimensional montmorillonite nanosheet is obtained by an inorganic modification or an organic modification; wherein the inorganic modification comprises using one or more of an inorganic acid and an inorganic salt to modify; the organic modification comprises using one or more of an organic acid, a surfactant, a polymer monomer, and a coupling agent to modify.

Optionally, in some embodiments, the solution including the two-dimensional montmorillonite nanosheet is a solution including a composite of the two-dimensional montmorillonite nanosheet and a polymer, and the polymer is selected from one or more of PMMA, PI, PAI, and PE.

Optionally, in some embodiments, a mass ratio of the polymer to the two-dimensional montmorillonite nanosheet is greater than 0:1 and less than or equal to 5:1.

Optionally, in some embodiments, the first electrode is selected from one or more of a metal electrode, a silicon carbon electrode, a doped or non-doped metal oxide electrode, and a composite electrode; wherein a material of the metal electrode is selected from one or more of Al, Ag, Cu, Mo, Au, Ba, and Ca; a material of the silicon carbon electrode is selected from one or more of silicon, graphite, carbon nanotube, graphene and carbon fiber; a material of the doped or non-doped metal oxide electrode is selected from one or more of AZO, GZO, IZO, and AMO; a material of the composite electrode is selected from one or more of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, TiO₂/Ag/TiO₂, and TiO₂/Al/TiO₂; the second electrode is selected from one or more of a metal electrode, a silicon carbon electrode, a doped or non-doped metal oxide electrode, and a composite electrode; wherein a material of the metal electrode is selected from one or more of Al, Ag, Cu, Mo, Au, Ba, and Ca; a material of the silicon carbon electrode is selected from one or more of silicon, graphite, carbon nanotube, graphene and carbon fiber; a material of the doped or non-doped metal oxide electrode is selected from one or more of ITO, FTO, ATO, AZO, GZO, IZO, MZO, and AMO; a material of the composite electrode is selected from one or more of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, TiO₂/Ag/TiO₂, and TiO₂/Al/TiO₂; a material of the light-emitting layer is selected from one or more of a quantum dot with single structure, a quantum dot with a core-shell structure, and a perovskite semiconductor material; the single structure quantum dot is selected from one or more of a group II-VI compound, a group IV-VI compound, a group III-V compound, a group I-III-VI compound; the group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe; the group IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe; the group III-V compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb; the group I-III-VI compound is selected from one or more of CuInS₂, CuInSe₂, and AgInS₂; a core of the quantum dot with a core-shell structure is selected from any one of the single structure quantum dots; a shell material of the quantum dot with a core-shell structure is selected from one or more of CdS, CdTe, CdSeTe, CdZnSe, CdZnS, CdSeS, ZnSe, ZnSeS, and ZnS; the perovskite semiconductor material is selected from a doped or non-doped inorganic perovskite type semiconductor, an organic perovskite semiconductor or an organic-inorganic hybrid perovskite type semiconductor; the inorganic perovskite type semiconductor has a general structural formula of AMX₃, wherein A is Cs⁺, M is a divalent metal cation which is selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, X is a halogen anion which is selected from one or more of Cl⁻, Br⁻, and I⁻; the organic-inorganic hybrid perovskite type semiconductor has a general structural formula of CMX₃, wherein C is a formamidyl, M is a divalent metal cation which is selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, X is a halogen anion which is selected from one or more of Cl⁻, Br⁻, and I⁻; the organic-inorganic hybrid perovskite type semiconductor has a general structural formula of BMX₃, wherein B is a Organic amine cation which is selected from one or more of CH₃(CH₂)ₙ₋₂NH₃⁺ or [NH₃(CH₂)ₙNH₃]²⁺, wherein n−2, M is a divalent metal cation which is selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, X is a halogen anion which is selected from one or more of Cl⁻, Br⁻, and I.

Correspondingly, the embodiment of the present disclosure also provide a display apparatus including the photoelectric device above.

### BENEFICIAL EFFECT

The photoelectric device of the present disclosure includes an anode, a light-emitting layer, an electronic function layer, and a cathode disposed in stack, wherein a material of the electronic function layer includes a two-dimensional montmorillonite nanosheet with anisotropic conductivity such that the electronic functional layer has a large band gap perpendicular to a film layer and a good conductivity along a surface direction of the film layer. On the one hand, it prevents electric charges from passing through an interface which acts as a charge blocking layer and improves a charge injection balance of the photoelectric device; On the other hand, electric charges are induced to conduct along a direction of interface extension, and the electric charges are uniformly transferred to a light-emitting layer along a surface direction in order to avoid a local accumulation of electric charges, thereby improving luminescence uniformity of the photoelectric device.

### BRIEF DESCRIPTION OF THE DRAWINGS

In order to illustrate the technical solutions in the embodiments of the present disclosure more clearly, accompanying drawings involved in the description of the embodiments will be briefly described below. It will be apparent that the accompanying drawings in the following description are merely some of the embodiments of the present disclosure, and other drawings may be obtained according to these drawings for those skilled in the art without involving any inventive effort.

FIG. 1 is a schematic structural diagram of a photoelectric device according to an embodiment of the present disclosure.

FIG. 2 is a flowchart showing steps of a method of preparing a photoelectric device according to an embodiment of the present disclosure.

FIG. 3 is a flowchart showing steps of a preparation method for a photoelectric device according to a specific embodiment of the present disclosure.

FIG. 4 is a flowchart showing steps of a preparation method for a photoelectric device according to another specific embodiment of the present disclosure.

### DETAILED DESCRIPTION OF EMBODIMENTS

Embodiments of the present disclosure will be described clearly and fully below in connection with the accompanying drawings in the embodiments of the present disclosure. It will be apparent that the described embodiments are merely a part of the embodiments of the present disclosure, rather than all the embodiments. Based on the embodiments in the present disclosure, all other embodiments obtained by a person skilled in the art without involving any inventive effort are within the scope of the present disclosure.

An embodiment of the present disclosure provides a photoelectric device and preparation method therefor, and display apparatus. Detailed descriptions are given below. It is to be noted that the order in which the following embodiments are described is not intended to define a preferred order of the embodiments. Additionally, in the description herein, the term “comprise” or “include” means “including, but not limited to”. Ranges may present in various embodiments of the present disclosure, and it is to be understood that the description of the ranges is merely for convenience and brevity and should not be construed as a limitation on the scope of the present disclosure. Accordingly, it is to be considered that the description of the ranges has particularly disclosed all possible subranges, as well as any single numerical value within that ranges. For example, it is to be considered that a range from 1 to 6 has particularly disclosed subranges, e.g., from 1 to 3, from 1 to 4, from 1 to 5, from 2 to 4, from 2 to 6, from 3 to 6, or the like, and single numerical values within the range, e.g., 1, 2, 3, 4, 5, or 6, which is applicable for any range. Additionally, whenever a range of values is indicated herein, it is meant to include any recited number (including a fractional or integer) within the indicated range.

In the present disclosure, the term “and/or”, indicating an association relationship of associated objects, means that there may be three relationships. For example, “A and/or B” may represent a case where A is present alone, a case where A and B are present at the same time, and a case where B is present alone, in which A and B may be a singular or plural.

In the present disclosure, the phrase “one or more” refers to one or a plurality of elements, and “more” in the “one or more” refers to two or more. The phrase “one or more”, “at least one”, or a similar expression, refers to any combination of these elements defined by the phrase, including a singular element or any combination of the plurality of elements. For example, “at least one of a, b, or c”, or “at least one of a, b, and c”, may represent: a, b, c, a-b (i.e., a and b), a-c, b-c, or a-b-c, in which a, b, and c may be a single or plural.

Referring to FIG. 1, An embodiment of the present disclosure provides a photoelectric device 100 including an anode 20, a light-emitting layer 30, an electronic function layer 10, and a cathode 40 sequentially disposed in stack.

A material of the electronic function layer 10 includes a two-dimensional montmorillonite nanosheet. Among them, Montmorillonite(MMT) is a aluminosilicate mineral of 2:1 type, that is, two layers of aluminosilicate tetrahedron sandwiched by a layer of aluminosilicate octahedron, and its crystal structure is Mₓ(Al₂-xMgₓ)[Si₄O₁₀](OH)₂. The Montmorillonite may be made into the two-dimensional nanosheet by mechanical exfoliation and other methods, and the two-dimensional nanosheet has excellent mechanical, optical and electrical properties. The two-dimensional montmorillonite nanosheet also has a property of conductivity anisotropy such that have a large band gap (4-9 eV) in a direction perpendicular to a surface, and a high conductivity (more than 10⁻³ S/m) in a direction along the surface.

In the embodiment, in one aspect, the electronic function layer 10 including the two-dimensional montmorillonite nanosheet prevents electric charges from passing through an interface connected with the light-emitting layer 30, and the electronic function layer 10 acts as a charge blocking layer, and improves a charge injection balance of the photoelectric device 100; In another aspect, electric charges are induced to conduct along a direction of interface extension, and the electric charges are uniformly transferred to the light-emitting layer 30 along a surface direction in order to avoid a local accumulation of electric charges, thereby improving luminescence uniformity of the photoelectric device 100. Improvements of charge injection balance and luminescence uniformity of the photoelectric device 100 further improves performance consistency, aging stability and lifespan of the photoelectric device 100.

Understandably, the material of the electronic function layer 10 may be the two-dimensional montmorillonite nanosheet only, and no other material may be included. In other embodiments, the material of the electronic functional layer 10 may include other materials in addition to the two-dimensional montmorillonite nanosheet, such as an electron blocking material known in the art.

In an embodiment, the material of the electronic function layer includes a composite of the two-dimensional montmorillonite nanosheet and a polymer. Wherein, the polymer is selected from one or more of PMMA, PI, PAI, and PE. Among them, the two-dimensional montmorillonite nanosheet is arranged directionally on a surface of a polymer film or inside the polymer film, and the two-dimensional montmorillonite nanosheet is parallel to the surface of the polymer film. The polymer is used as a support matrix of the two-dimensional montmorillonite nanosheet in the composite, and a band gap of functional layers is regulated and broadened. Furthermore, a mass ratio of the polymer to the two-dimensional montmorillonite nanosheet in the composite is greater than 0:1 and less than or equal to 5:1. An excessive content of the polymer in the composite leads to a poor conductivity of a functional layer, and the functional layer is not conducive for carrier migration.

Specifically, the two-dimensional montmorillonite nanosheet may be selected from one or more of a calcium-based two-dimensional montmorillonite nanosheet, a sodium-based two-dimensional montmorillonite nanosheet, a sodium-calcium-based two-dimensional montmorillonite nanosheet, and a magnesium-based two-dimensional montmorillonite nanosheet.

Among them, the calcium-based, the sodium-based, the sodium-calcium-based, and the magnesium-based are classified by types of exchangeable cations between multiple natural montmorillonite layers. The two-dimensional montmorillonite nanosheet with different cationic groups all have good anisotropic conductivity, but there may be some differences in other properties, such as the sodium-calcium-based two-dimensional montmorillonite nanosheet has better distensibility and heat stability than the calcium-based two-dimensional montmorillonite nanosheet.

In order to regulate cation concentration, electrical conductivity, and hydrophobicity of the two-dimensional montmorillonite nanosheet, thereby improving the feasibility of preparing an electronic functional layer 10 including the two-dimensional montmorillonite nanosheet, and improving the heat stability and electrical conductivity of the electronic functional layer 10, the two-dimensional montmorillonite nanosheet in the embodiment can be obtained by mechanical exfoliation or other methods from a natural montmorillonite, or the two-dimensional montmorillonite nanosheet may be a modified two-dimensional montmorillonite nanosheet which is obtained by different modification treatments.

In an embodiment, the two-dimensional montmorillonite nanosheet is obtained by an inorganic modification or an organic modification; wherein the inorganic modification includes using one or more of an inorganic acid and an inorganic salt to modify; the organic modification includes using one or more of an organic acid, a surfactant, a polymer monomer, and a coupling agent to modify. The modified two-dimensional montmorillonite nanosheet corresponding to different modification methods may be directly purchased from a market, or may be prepared by multiple modification methods known in the art.

Specifically, Using the inorganic acid or the organic acid to modify, that is, the two-dimensional montmorillonite nanosheet may be modified by the inorganic acid or the organic acid. Among them, the inorganic acid is selected from one or more of sulfuric acid, hydrochloric acid, nitric acid, and phosphoric acid, and the organic acid is selected from one or more of a carboxylic acid, a sulfonic acid, a sulfinic acid, and a thiocarboxylic acid. The modification of the inorganic acid or the organic acid transforms some cations among layers of the two-dimensional montmorillonite nanosheet into an acid-soluble salt to dissolve out thereby weakening a binding force between original layers, improving layer spacing, and enhancing heat stability.

Wherein, the inorganic salt which is configured to modify is selected from one or more of a halogen salt, a nitrate, a sulfate, a phosphate, a carboxylate salt, a sulfonate, a sulfinate, and a thiocarboxylate salt including aluminum, magnesium, zinc, copper, sodium and so on. The two-dimensional montmorillonite nanosheet modified by the inorganic salt can carry out cation exchange. Compared with the calcium-based, the magnesium-based, and the sodium-based two-dimensional montmorillonite nanosheet, the modified two-dimensional montmorillonite nanosheet has better performance in solution dispersion, heat stability, and conductivity. An inorganic salt-modified two-dimensional montmorillonite nanosheet can improve the feasibility of preparing electronic functional layer 10 by solution methods, as well as the heat stability and film conductivity of the electronic functional layer 10.

Wherein, the organic modification includes using one or more of o an organic acid, a surfactant, a polymer monomer, and a coupling agent to modify. Since inorganic ions in a montmorillonite are oleophobic, it is not conducive to the dispersion of the montmorillonite in a polymer matrix. The organic modification such as the surfactant, the polymer monomer, or the coupling agent is employed to enhance the polarity of a surface of the montmorillonite, so that an intersoil layer of he montmorillonite can change from hydrophilic to lipophilic, reduce the surface energy, and increase layer distance of the montmorillonite, which is conducive to prepare the electronic function layer 10 by a solution method.

Wherein, the surfactant is selected from one or more of a cationic surfactant, an anionic surfactant, and a nonionic surfactant. The polymer monomer is selected from one or more of methyl methacrylate, N-vinyl pyrrolidone, pyrrole, ethylene terephthalate, and ethylene naphthalate. The polymer monomer does not polymerize, and the polymer monomer acts as the surfactant, and properties of the polymer monomer such as solubility will not have a negative impact on a device. Wherein, the coupling agent is selected from one or more of a silane coupling agent, a titanate coupling agent, and a polyurethane coupling agent.

In an embodiment, a thickness of the electronic functional layer may be 1 nm to 50 nm, such as 5 nm-50 nm, 5 nm-40 nm, 10 nm-40 nm, 20 nm-40 nm, 20 nm-30 nm, 5 nm, 10 nm, 20 nm, or 50 nm. If the thickness of the electronic functional layer is too thick, it may affect the conductivity of the device. If the thickness of the electronic functional layer is too small, it may not be able to form a uniform electronic functional layer and obtain a uniform conductivity anisotropy.

A material of the anode 20 is a material known in the art for an anode, and a material of the cathode 40 is a material known in the art for an anode. The anode 20 and the cathode 40 may be each independently selected from one or more of a metal electrode, a silicon carbon electrode, a doped or non-doped metal oxide electrode, and a composite electrode; wherein, a material of the metal electrode is selected from one or more of Al, Ag, Cu, Mo, Au, Ba, and Ca; a material of the silicon carbon electrode is selected from one or more of silicon, graphite, carbon nanotube, graphene and carbon fiber; a material of the composite electrode is selected from one or more of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, TiO₂/Ag/TiO₂, and TiO₂/Al/TiO₂. Among them, “/” represents a laminated structure, for example, a composite electrode AZO/Ag/AZO represents an electrode with a composite structure which is formed of a AZO layer, a Ag layer, and a AZO layer disposed in stack. A thickness of the anode 20 may be, for example, 10 nm to 100 nm, such as 10 nm, 30 nm, 40 nm, 50 nm, 60 nm, 80 nm, or 100 nm; A thickness of the cathode 40 may be, for example, 15 nm to 100 nm, such as 15 nm, 30 nm, 40 nm, 50 nm, 60 nm, 80 nm, or 100 nm.

The light-emitting layer 30 may be a quantum dot luminescent layer, and accordingly the photoelectric device 100 may be a quantum dot light-emitting diode. A thickness of the light-emitting layer 30 may be a thickness range of a light-emitting layer in a conventional quantum dot light-emitting device, for example, 10 nm to 60 nm, such as 10 nm, 15 nm, 20 nm, 25 nm, 30 nm, 40 nm, 50 nm, or 60 nm, or the hickness of the light-emitting layer 30 may be 10 nm to 25 nm.

Wherein, a material of the quantum dot luminescent layer is a quantum dot known in the art for a quantum dot luminescent layer, such as one of a red quantum dot, a green quantum dot, and a blue quantum dot.

The quantum dot may be selected from at least one of a quantum dot with single structure, a quantum dot with a core-shell structure, and a perovskite semiconductor material, and the single structure quantum dot is selected from one or more of a group II-VI compound, and a group IV-VI compound, a group III-V compound, a group I-II-VI compound, and the group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe, and the group IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe and SnPbSTe, and the group III-V compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs and InAlPSb, and the group I-III-VI compound is selected from one or more of CuInS₂, CuInSe₂ and AgInS₂. A shell material of the quantum dot with a core-shell structure is selected from one or more of CdS, CdTe, CdSeTe, CdZnSe, CdZnS, CdSeS, ZnSe, ZnSeS, and ZnS. It should be noted that for aforementioned the single structure quantum dot, or the shell material of the quantum dot with a core-shell structure, or a material of the shell of the quantum dot with a core-shell structure, a chemical formula provided only indicates an element composition, but does not indicate a content of each element. For example, CdZnSe only represents a composition of three elements: Cd, Zn, and Se.

If the content of each element is represented, the chemical formula corresponds to be CdₓZnixSe, 0<x<1.

The perovskite semiconductor material is selected from a doped or non-doped inorganic perovskite type semiconductor, an organic perovskite semiconductor or an organic-inorganic hybrid perovskite type semiconductor; the inorganic perovskite type semiconductor has a general structural formula of AMX₃, wherein A is Cs⁺, M is a divalent metal cation which is selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, X is a halogen anion which is selected from one or more of Cl⁻, Br⁻, and I⁻; the organic-inorganic hybrid perovskite type semiconductor has a general structural formula of CMX₃, wherein C is a formamidyl, and M is a divalent metal cation which includes but not limited to one or more of Pb²⁺, Sn²⁺, Cu²⁺, Ni²⁺, Cd²⁺, Cr², Mn²⁺, Co²⁺, Fe²⁺, Ge²⁺, Yb²⁺, and Eu²⁺, and X is a halogen anion which includes but not limited to one or more of Cl⁻, Br⁻, and I⁻; The organic-inorganic hybrid perovskite type semiconductor has a general structural formula of BMX₃, wherein B is an Organic amine cation which includes but not limited to CH₃(CH₂)ₙ₋₂NH₃⁺ or [NH₃(CH₂)ₙNH₃]²⁺, wherein n≥2, and M is a divalent metal cation which includes but not limited to one or more of Pb²⁺, Sn²⁺, Cu²⁺, Ni²⁺, Cd²⁺, Cr²⁺, Mn²⁺, C02+, Fe²⁺, Ge²⁺, Yb²⁺, and Eu²⁺, and X is a halogen anion which is selected from one or more of Cl⁻, Br⁻, and I.

Furthermore, referring to FIG. 1, in an embodiment, the photoelectric device 100 further includes a hole transport layer 50, and the hole transport layer 50 is disposed between the anode 20 and the light-emitting layer 30. A material of the hole transport layer 50 may be selected from organic materials with hole transport capability, including but not limited to one or more of Poly(9,9-dioctylfluorene-co-N-(4-butylphenyl)diphenylamine)(TFB), poly(n-vinylcarbazole)(PVK), poly[N,N′-bis(4-butylphenyl)-N,N′-bis(phenyl)-benzidine](poly-TPD), poly(9,9-dioctylfluorene-co-bis-N,N-phenyl-1,4-phenylenediamine)(PFB), 4,4′,4″-tris(carbazol-9-yl)-triphenylamine(TCATA), 4,4′-bis(9-carbazolyl)-1,1′-biphenyl)(CBP), N,N′-bis-(3-methylphenyl)-N,N′-Bis-phenyl-(1,1′-biphenyl)-4,4′-diamine(TPD), N,N′-Bis(1-naphthalenyl)-N,N′-bisphenyl-(1,1′-biphenyl)-4,4′-diamine, doped graphene, undoped graphene, and C60. The material of the hole transport layer 50 may be selected from inorganic materials with hole transport capability, including but not limited to one or more of doped or non-doped NiO, WO₃, MoO₃, and CuO. A thickness of the hole transport layer 50 is a thickness of a conventional hole transport layer, for example, may be 10 nm to 100 nm, such as 10 nm, 20 nm, 30 nm, 40 nm, 50 nm, 60 nm, and 100 nm. Alternatively, the hole transport layer 50 may have a thickness range of 20-60 nm.

Furthermore, in an embodiment, the photoelectric device 100 may further includes a hole injection layer 60, and the hole injection layer 60 is disposed on a surface of the anode 20 facing one side of the cathode 40. When the photoelectric device 100 includes the hole injection layer 60 and the the hole transport layer 50, the hole injection layer 60 is disposed between the anode 20 and the hole transport layer 50. When the photoelectric device 100 includes the hole injection layer 60 but does not include the hole transport layer 50, the hole injection layer 60 is disposed between the anode 20 and the light-emitting layer 30. In the above two different cases, the hole injection layer 60 is disposed on the surface of the anode 20 facing the side of the cathode 40, and the hole injection layer 60 is in contact with and connected to the anode 20.

A material of the hole injection layer 60 is a material known in the art for a hole injection layer, and the material of the hole injection layer 60 may be selected from materials with hole transport capability, including but not limited to one or more of poly(3,4-ethylenedioxythiophene)(PEDOT), poly(3,4-ethylenedioxythiophene)-poly(styrenesulfonate)(PEDOT:PSS), 2,3,5,6-tetrafluoro-7,7,8,8-tetracyanoquinodimethane(F4-TCNQ), hexaazatriphenylenehexacabonitrile(HATCN), copper phthalocyanine(CuPc), transition metal oxides, and transition metal chalcogenides. A thickness of the hole injection layer 60 is a thickness of a conventional hole injection layer, for example, may be 20 nm to 80 nm, such as 20 nm to 70 nm, 20 nm to 60 nm, 30 nm to 70 nm, 30 nm to 60 nm, 40 nm to 60 nm, 40 nm to 50 nm, 20 nm, 30 nm, 40 nm, 50 nm, 60 nm, and 80 nm. In one specific embodiment, the hole injection layer 60 may have a thickness range of 20 nm to 60 nm.

Furthermore, in an embodiment, the photoelectric device 100 may further include an electron transport layer 70, and the electron transport layer 70 is disposed between the electronic function layer 10 and the cathode 40. A material of the electron transport layer 70 is a material known in the art for an electron transport layer, such as including but not limited to one or more of an inorganic nanocrystalline material, a doped inorganic nanocrystalline material, and an organic material. The inorganic nanocrystalline material may include one or more of ZnO, NiO, W₂O₃, Mo₂O₃, TiO₂, SnO, ZrO₂, Ta₂O₃, Ga₂O₃, SiO₂, Al₂O₃, and CaO, and the doped inorganic nanocrystalline material may include one or more of a doped zinc oxide, a doped titanium dioxide, a doped tin dioxide, wherein the doped inorganic nanocrystalline material is an inorganic material doped with other elements, and doped elements are selected from Mg, Ca, Li, Ga, Al, Co, Mn, and so on; The organic material may include one or two of polymethyl methacrylate and polyvinyl butyral.

A thickness of the electron transport layer 70 is a thickness of a conventional electron transport layer, for example, may be 20 nm to 60 nm, such as 20 nm to 50 nm, 30 nm to 50 nm, 30 nm to 40 nm, 20 nm, 30 nm, 40 nm, 50 nm, and 60 nm. In one specific embodiment, the electron transport layer 70 may have a thickness range of 25 nm to 60 nm.

Furthermore, in an embodiment, the photoelectric device 100 may further include an electron injection layer 80, and the electron injection layer 80 is disposed between the electronic function layer 10 and the cathode 40. Furthermore, a surface of the electron injection layer 80 is connected to a surface of the cathode 40 that faces one side of the anode 20. When the photoelectric device 100 include the electron transport layer 70 and the electron injection layer 80, the electron injection layer 80 is disposed between the cathode 40 and the electron transport layer 70, that is, the electron injection layer 80 is disposed close to one side of the cathode 40, and the electron transport layer 70 is disposed close to one side of the electron function layer 10. A material of the electron injection layer 80 is a material known in the art for an electron injection layer, such as including but not limited to LiF, MgP, MgF₂, Al₂O₃, Ga₂O₃, ZnO, Cs₂CO₃, RbBr, Rb₂CO₃, and LiF/Yb. A thickness of the electron injection layer 80 is a thickness of a conventional electron transport layer, for example, may be 10 nm to 30 nm, such as 10 nm to 25 nm, 15 nm to 25 nm, 15 nm to 20 nm, 10 nm, 20 nm, and 30 nm.

It can be understood that in addition to the above functional layers, some functional layers that are conventionally applied in a photoelectric device and help to improve the performance of the photoelectric device may also be added, such as a hole blocking layer and an interface modification layer.

It can be understood that the material and thickness of each layer of the photoelectric device may be adjusted according to a light-emitting requirement of the photoelectric device 100.

In some embodiments of the present disclosure, the photoelectric device 100 is a quantum dot light-emitting diode, and the photoelectric device 100 may be a quantum dot light-emitting diode with a positive structure or a quantum dot light-emitting diode with an inverted structure. A substrate of the quantum dot light-emitting diode with a positive structure is connected to the anode, and A substrate of the quantum dot light-emitting diode with an inverted structure is connected to the cathode.

An embodiment of the present disclosure also provides a display device including the photoelectric device provided in the present disclosure. The display device may be any electronic product with a display function, including but not limited to a smartphone, a tablet computer, a notebook computer, a digital camera, a digital video camera, a smart wearable device, a smart weighing electronic scale, a vehicle display, a television or an electronic book, wherein the smart wearable device may be, for example, a smart bracelet, a smart watche, a virtual reality (VR) helmet and so on.

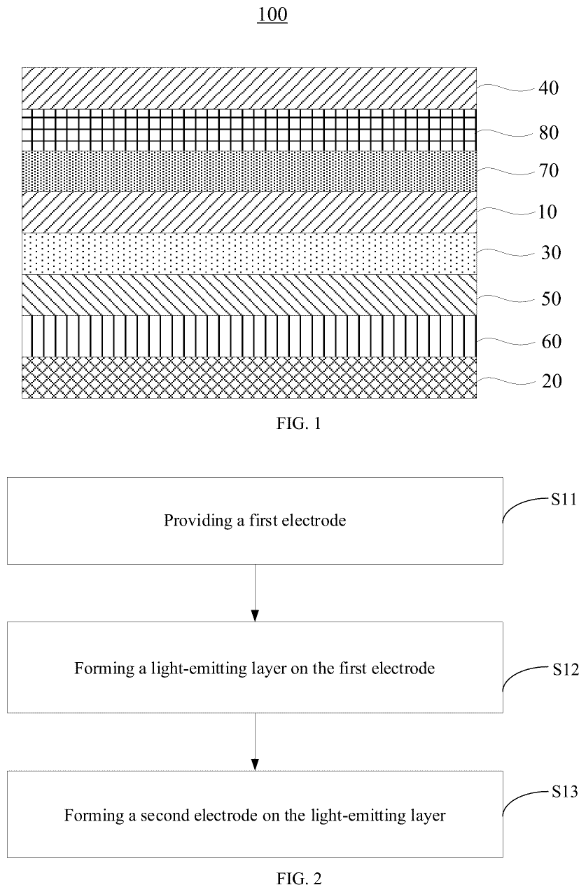

Referring to FIG. 2, FIG. 2 is a flow diagram of an embodiment of a preparation method for a photoelectric device provided in the present disclosure, and the preparation method specifically includes the following steps: Step S11: Providing a first electrode; Step S12: Forming a light-emitting layer on the first electrode; Step S13: Forming a second electrode on the light-emitting layer; The method further includes obtaining an electronic functional layer by using a solution including the two-dimensional montmorillonite nanosheet with a solution method, wherein the electronic functional layer and the light-emitting layer are disposed between the first electrode and the second electrode.

In the embodiment, the first electrode and the second electrode are a pair of electrodes. The first electrode is an anode, and the second electrode is a cathode. The first electrode is a cathode, and the second electrode is an anode.

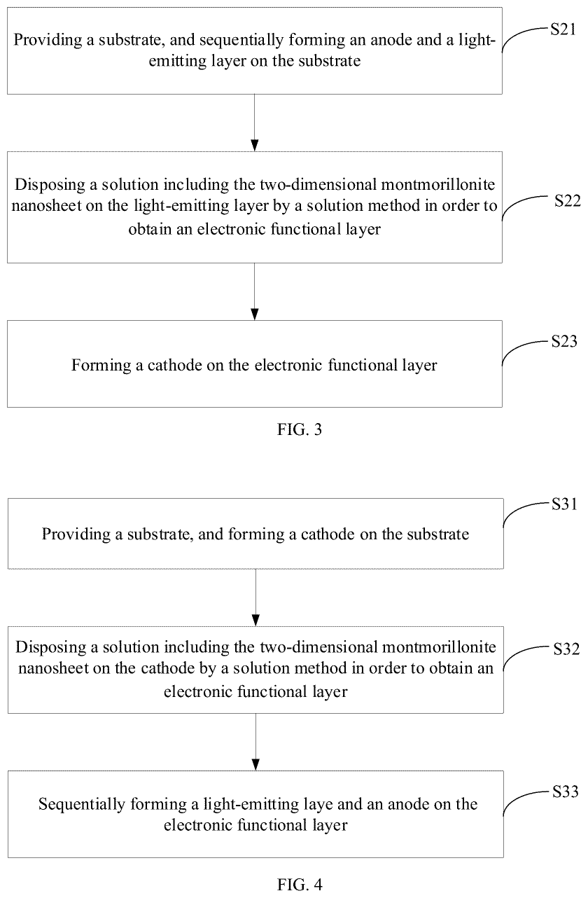

In an embodiment, the first electrode is the anode, and the second electrode is the cathode, and prior to forming the second electrode, the obtaining an electronic functional layer by using a solution including the two-dimensional montmorillonite nanosheet with a solution method comprises disposing the solution including the two-dimensional montmorillonite nanosheet on the light-emitting layer by the solution method. In particular, referring to FIG. 3, FIG. 3 is a flowchart showing steps of a preparation method for a photoelectric device according to a specific embodiment of the present disclosure.

In another embodiment, the first electrode is the cathode, and the second electrode is the anode, and prior to forming the light-emitting layer, the obtaining an electronic functional layer by using a solution including the two-dimensional montmorillonite nanosheet with a solution method comprises disposing the solution including the two-dimensional montmorillonite nanosheet on the first electrode by the solution method. In particular, referring to FIG. 4, FIG. 4 is a flowchart showing steps of a preparation method for a photoelectric device according to another specific embodiment of the present disclosure.

In a specific embodiment, referring to FIG. 3, an embodiment of the present disclosure provides a preparation method for a photoelectric device, and the photoelectric device is a quantum dot light-emitting diode with the positive structure, and the preparation method includes the following steps:
Step S21: Providing a substrate, and sequentially forming an anode and a light-emitting layer on the substrate.
Step S22: Disposing a solution including the two-dimensional montmorillonite nanosheet on the light-emitting layer by a solution method in order to obtain an electronic functional layer.
Step S23: Forming a cathode on the electronic functional layer.

Furthermore, the two-dimensional montmorillonite nanosheet in step S22 may be commercially available, or may be prepared by a conventional method. A preparation method for the two-dimensional montmorillonite nanosheet may be as following: providing a chunk of montmorillonite, obtaining a primary product of the two-dimensional montmorillonite nanosheet by mechanical exfoliation or ball milling, dissolving and dispersing the primary product by an organic solvent such as N,N-dimethylformamide, N-methylpyrrolidone, acetone or ether, and performing a first filtration, and obtaining a filtrate as an initial dispersion of the two-dimensional montmorillonite nanosheet; the two-dimensional montmorillonite nanosheet is obtained by a ultrasonic treatment of the initial dispersion and a second filtration. Filter holes of the first filtration are larger to filter out large unstripped solids, and filter holes of the second filtration are smaller to remove a filtrate, and a filter cake obtained is the two-dimensional montmorillonite nanosheet with relatively uniform size and high purity. Furthermore, the two-dimensional montmorillonite nanosheet obtained above may also be modified by a modification method such as an acid modification, an inorganic salt modification or an organic modification. The modification method may be a conventional modification method, and it is not limited here.

It can be understood that when the photoelectric device also includes the hole transport layer and/or the hole injection layer, the step S21 is to provide the substrate and form the hole injection layer and/or the hole transport layer, and the light-emitting layer sequentially on the anode. When the photoelectric device further includes the electron transport layer and/or the electron injection layer, step S23 is to form the electron transport layer and/or the electron injection layer, and the cathode sequentially on the electronic function layer.

Specifically, in the step S1 and the step S23, a method for forming the anode, the light-emitting layer, the cathode, the hole transport layer, the hole injection layer, the electron transport layer, and the electron injection layer may be realized using multiple conventional techniques in the art, including, but not limited to a solution method and a deposition method, wherein the solution method including, but not limited to a spin coating process, a coating process, an inkjet printing process, a scratch coating process, a dip coating process, a soaking process, a spray coating process, a roller coating process or a casting process; The deposition method includes an chemical method and a physical method, and the chemical method includes but not limited to a chemical vapor deposition method, a continuous ionic layer adsorption and reaction method, an anodic oxidation method, an electrolytic deposition method, or a co-precipitation method. The physical method includes but not limited to a thermal evaporation deposition method, an electron beam evaporation deposition method, a magnetron sputtering method, a multi-arc ion deposition method, a physical vapor deposition method, an atomic layer deposition method, or a pulsed laser deposition method. When the solution method is configured to prepare each layer structure including the electronic function layer 10, a drying process is needed. Wherein, the drying process may be an annealing process. Among them, the “annealing process” includes all processes that can make a wet film obtain higher energy, so as to change from a wet film state to a dry film state. For example, the “annealing process” may only refer to a heat treatment process, that is, heating the wet film to a specific temperature and then maintaining it for a specific period of time so that a solvent in the wet film is fully volatilized; for another example, the “annealing process” may also includes a thermal treatment process and a cooling process sequentially performed, that is, the wet film is heated to a specific temperature, and then held for a specific time to allow the solvent in the wet film to fully volatilize, and then cooled at an appropriate rate to eliminate residual stress so as to reduce risk of layer deformation and cracking of a dry hole transport film.

Among them, materials of the anode, the light-emitting layer, the cathode, the hole transport layer, the hole injection layer, the electron transport layer and the electron injection layer may be referred to a relevant description above.

In another specific embodiment, referring to FIG. 4, an embodiment of the present disclosure provides another preparation method for a photoelectric device, and the photoelectric device is a quantum dot light-emitting diode with the inverted structure, and the preparation method includes the following steps:
Step S31: Providing a substrate, and forming a cathode on the substrate.
Step S32: Disposing a solution including the two-dimensional montmorillonite nanosheet on the cathode by a solution method in order to obtain an electronic functional layer.
Step S33: Sequentially forming a light-emitting layer and an anode on the electronic functional layer.

It can be understood that when the photoelectric device also includes the hole transport layer and/or the hole injection layer, the step S33 is to form the light-emitting layer, the hole transport layer and/or the hole injection layer, and the anode sequentially on the electronic functional layer. When the photoelectric device further includes the electron transport layer and/or the electron injection layer, the step S31 is to provide the substrate and form the cathode on the substrate, and form the electron transport layer and/or the electron injection layer, and the cathode on the electronic functional layer.

Methods of forming the anode, the light-emitting layer, the cathode, the hole transport layer, the hole injection layer, the electron transport layer and the electron injection layer in the embodiment may be referred to the relevant description in the previous embodiment, and will not be detailed here.

It is understood that when the photoelectric device also includes other functional layers such as an electron blocking layer, a hole blocking layer and/or an interface modification layer, the preparation method for the photoelectric device also includes steps to form each of the functional layers.

It is understood that the preparation method for the photoelectric device also includes an encapsulating step, and an encapsulating material may be acrylic resins or epoxy resins, and the encapsulating step may be realized by commonly used machines or manually, and a UV curable adhesive may be configured to encapsulate, and both the oxygen content and the water content in environment where the encapsulating step is performed are lower than 0.1 ppm to ensure the stability of the photoelectric device.

It should be noted that the solution including the two-dimensional montmorillonite nanosheet is used in the preparation method of the electronic functional layer in the embodiments, wherein the two-dimensional montmorillonite nanosheet is obtained by the inorganic modification or the organic modification; Among them, the inorganic modification includes using at least one of an inorganic acid and an inorganic salt to modify; the organic modification includes using at least one of an organic acid, a surfactant, a polymer monomer, and a coupling agent to modify. In addition, a preparation of the solution including the two-dimensional montmorillonite nanosheet may also be a solution including a composite of the two-dimensional montmorillonite nanosheet and a polymer, so that the electronic functional layer 10 include a composit of the two-dimensional montmorillonite nanosheet and the polymer. Wherein, the polymer is selected from at least one of PMMA, PI, PAI, and PE. Among them, the specific description of the modified two-dimensional montmorillonite nanosheet and the composit of the modified two-dimensional montmorillonite nanosheet and the polymer may refer to the relevant description above, which will not be repeated here.

The following is a detailed description of technical proposals and beneficial effects of the present disclosure through specific embodiments, comparative examples, and test examples. The following embodiments are only part of implementation examples of the present disclosure, and are not specifically limited to the present disclosure.

### EXAMPLE 1

The embodiment provides a quantum dot electroluminescent diode with the positive structure, and the preparation method for the quantum dot electroluminescent diode includes the following steps:

An ITO substrate was provided, and a thickness of a substrate glass was 0.55 mm, and a thickness of the ITO substrate was 50 nm. After cleaning and drying the ITO substrate, it was treated with UV ozone for 15 min to serve as an anode 20 and a substrate.

Under an atmospheric environment of a normal temperature and pressure, a PEDOT solution was spin-coated on one side of the ITO substrate, and then subjected to a constant temperature heat treatment at 150° C. for 15 minutes to obtain a hole injection layer 60 with a thickness of 35 nm.

Under a nitrogen environment of a normal temperature and pressure, a TFB-chlorobenzene solution with a concentration of 9 mg/mL was spin-coated on the hole injection layer 60, and then subjected to a constant temperature heat treatment at 150° C. for 30 minutes to obtain a hole transport layer 50 with a thickness of 40 nm.

Under a nitrogen environment of a normal temperature and pressure, a green quantum dot CdSe/ZNS-n-octane solution with a concentration of 10 mg/mL was spin-coated on the hole transport layer 50 and then subjected to a constant temperature heat treatment at 80° C. for 10 minutes to obtain a light-emitting layer 30 with a thickness of 15 nm.

A dispersion solution of the calcium-based two-dimensional montmorillonite nanosheet and N,N-dimethyl-formamide with a concentration of 35 mg/mL was prepared, and the dispersion solution was spin-coated on the light-emitting layer 30 and then subjected to a constant temperature heat treatment at 120° C. for 30 minutes to obtain an electronic function layer 10 with a thickness of 15 nm.

Under a nitrogen environment of a normal temperature and pressure, a nano ZnO-ethanol solution with a concentration of 30 mg/mL was spin-coated on the electronic functional layer 10 and then subjected to a constant temperature heat treatment at 80° C. for 30 minutes to obtain an electron transport layer 70 with a thickness of 40 nm.

Ag was deposited on the electron transport layer 70 by a vacuum evaporation method to obtain a cathode 40 with a thickness of 50 nm.

The quantum dot electroluminescent diode with the positive structure was obtained by an encapsulating step.

### EXAMPLE 2

The embodiment provides a quantum dot electroluminescent diode, and compared with the quantum dot electroluminescent diode of example 1, the quantum dot electroluminescent diode of the embodiment only has a difference that the two-dimensional montmorillonite nanosheet included in the electronic functional layer 10 is a montmorillonite nanosheet modified by acetic acid. A preparation method is as follows: a dispersion solution of the montmorillonite nanosheet modified by acetic acid and N,N-dimethyl-formamide with a concentration of 35 mg/mL was prepared, and the dispersion solution was spin-coated on the light-emitting layer 30 and then subjected to a constant temperature heat treatment at 120° C. for 30 minutes to obtain an electronic function layer 10 with a thickness of 15 nm.

### EXAMPLE 3

The embodiment provides a quantum dot electroluminescent diode, and compared with the quantum dot electroluminescent diode of example 1, the quantum dot electroluminescent diode of the embodiment only has a difference that the two-dimensional montmorillonite nanosheet included in the electronic functional layer 10 is a montmorillonite nanosheet modified by NaCl. A preparation method is as follows: a dispersion solution of the montmorillonite nanosheet modified by NaCl and N,N-dimethyl-formamide with a concentration of 35 mg/mL was prepared, and the dispersion solution was spin-coated on the light-emitting layer 30 and then subjected to a constant temperature heat treatment at 120° C. for 30 minutes to obtain an electronic function layer 10 with a thickness of 15 nm.

### EXAMPLE 4

The embodiment provides a quantum dot electroluminescent diode, and compared with the quantum dot electroluminescent diode of example 1, the quantum dot electroluminescent diode of the embodiment only has a difference that the two-dimensional montmorillonite nanosheet included in the electronic functional layer 10 is a montmorillonite nanosheet modified by octadecyl trimethyl quaternary ammonium salt. A preparation method is as follows: a dispersion solution of the montmorillonite nanosheet modified by octadecyl trimethyl quaternary ammonium salt and N,N-dimethyl-formamide with a concentration of 35 mg/mL was prepared, and the dispersion solution was spin-coated on the light-emitting layer 30 and then subjected to a constant temperature heat treatment at 120° C. for 30 minutes to obtain an electronic function layer 10 with a thickness of 15 nm.

### EXAMPLE 5

The embodiment provides a quantum dot electroluminescent diode, and compared with the quantum dot electroluminescent diode of example 1, the quantum dot electroluminescent diode of the embodiment only has a difference that the two-dimensional montmorillonite nanosheet included in the electronic functional layer 10 is a montmorillonite nanosheet modified by N-vinyl-2-pyrrolidone. A preparation method is as follows: a dispersion solution of the montmorillonite nanosheet modified by N-vinyl-2-pyrrolidone and N,N-dimethyl-formamide with a concentration of 35 mg/mL was prepared, and the dispersion solution was spin-coated on the light-emitting layer 30 and then subjected to a constant temperature heat treatment at 120° C. for 30 minutes to obtain an electronic function layer 10 with a thickness of 15 nm.

### EXAMPLE 6

The embodiment provides a quantum dot electroluminescent diode, and compared with the quantum dot electroluminescent diode of example 1, the quantum dot electroluminescent diode of the embodiment only has a difference that the two-dimensional montmorillonite nanosheet included in the electronic functional layer 10 is a montmorillonite nanosheet modified by triethoxyvinylsilane. A preparation method is as follows: a dispersion solution of the montmorillonite nanosheet modified by triethoxyvinylsilane and N,N-dimethyl-formamide with a concentration of 35 mg/mL was prepared, and the dispersion solution was spin-coated on the light-emitting layer 30 and then subjected to a constant temperature heat treatment at 120° C. for 30 minutes to obtain an electronic function layer 10 with a thickness of 15 nm.

### EXAMPLE 7

The embodiment provides a quantum dot electroluminescent diode, and compared with the quantum dot electroluminescent diode of example 1, the quantum dot electroluminescent diode of the embodiment only has a difference that the two-dimensional montmorillonite nanosheet included in the electronic functional layer 10 is the composite of the calcium-based two-dimensional montmorillonite nanosheet and PMMA. A preparation method is as follows: a dispersion solution of the calcium-based two-dimensional montmorillonite nanosheet and N,N-dimethyl-formamide with a concentration of 35 mg/mL was prepared, and the dispersion solution was spin-coated on the light-emitting layer 30 and then subjected to a constant temperature heat treatment at 120° C. for 30 minutes to obtain an electronic function layer 10 with a thickness of 15 nm.

### EXAMPLE 8

The embodiment provides a quantum dot electroluminescent diode, and compared with the quantum dot electroluminescent diode of example 1, the quantum dot electroluminescent diode of the embodiment only has a difference that the thickness of the electronic function layer 10 is 15 nm.

### EXAMPLE 9

The embodiment provides a quantum dot electroluminescent diode, and compared with the quantum dot electroluminescent diode of example 1, the quantum dot electroluminescent diode of the embodiment only has a difference that the thickness of the electronic function layer 10 is 50 nm.

### COMPARATIVE EXAMPLE

The comparative example provides a quantum dot electroluminescent diode, and compared with the quantum dot light-emitting diode of Example 1, the quantum dot electroluminescent diode of the embodiment only has a difference that the electron functional layer 10 is not included between light-emitting layer 30 and the electron transport layer 70. Accordingly, a preparation process of the electron functional layer 10 was not included in the preparation method, and the electron transport layer 70 was directly formed on the light-emitting layer 30.

Performances of quantum dot electroluminescent diodes of the Example 1 to Example 9 and the Comparative Example are tested by a silicon photoelectric testing instrument and an imaging luminance meter. Performance test items are as follows: an external quantum efficiency (EQE, %), an electroluminescence (EL) uniformity, and a time required for luminance attenuation from 100% to 95% at 1000 Nits in a quantum dot electroluminescent diode(T95@1000 nits, h). Performance test results are shown in Table 1 below.

TABLE 1

| | | uniformity | T95@1000 |
|---|---|---|---|
| | EQE | of EL | nits |
| | (%) | (%) | (h) |
| Comparative Example | 11.2 | 85.1 | 4500 |
| Example 1 | 19.6 | 94.3 | 9000 |
| Example 2 | 20.7 | 92.1 | 8000 |
| Example 3 | 23.5 | 94.3 | 12000 |
| Example 4 | 19.8 | 94.8 | 9600 |
| Example 5 | 20.7 | 96.5 | 13000 |
| Example 6 | 22.6 | 97.6 | 12500 |
| Example7 | 21.6 | 96.9 | 14000 |
| Example 8 | 23.8 | 98.9 | 14500 |
| Example 9 | 18.1 | 99.2 | 8500 |

It can be seen from Table 1 that compared with the quantum dot electroluminescent diodes with a EQE of 11.2%, an EL uniformity of 85.1%, and a T95 of 4500 h in the Comparative Example, the performances of quantum dot light-emitting diodes of the Example 1 to Example 9 have obvious advantages. In Example 1 to Example 9, the EQE of the quantum dot light-emitting diode can reach 18.1% to 23.8%, the EL uniformity can reach 92.1% to 99.2%, the T95 @1000 nits can reach 8000 h to 14500 h, and the luminescence efficiency, the luminescence uniformity, the lifespan and other aspects of an overall device are significantly improved compared with the Comparative Example.

Electronic functional layers of light-emitting diodes in Example 1, Example 8, and Example 9 include the calcium-based two-dimensional montmorillonite nanosheet, and electronic functional layers of light-emitting diodes in Example 2 to Example 6 include the modified two-dimensional montmorillonite nanosheet modified by an acid modification, an inorganic salt modification and the like, and the electronic functional layer of a light-emitting diode in Example 7 is the composite including the calcium-based two-dimensional montmorillonite nanosheet and the polymer of PMMA, thereby improving the external quantum efficiency, the luminescence uniformity, and the lifespan of the light-emitting diodes. Therefore, it can be explained that the quantum dot electroluminescent diodes including the electronic functional layer of the present disclosure can improve the charge injection balance of the device to improve the luminescence efficiency, and induce the conduction of the charge extension interface extension direction, and uniformly transmit the charge to the luminescent layer along the surface direction, so as to avoid local accumulation of charges, thereby improving the luminescence uniformity and the lifespan of the device, wherein the material of the electronic functional layer includes a two-dimensional montmorillonite nanosheet.

Electronic functional layers of light-emitting diodes in Example 1, Example 8, and Example 9 all include the calcium-based two-dimensional montmorillonite nanosheet, and thicknesses of the electronic functional layers are 15 nm, 5 nm, and 50 nm, respectively, and the EL uniformity of light-emitting devices are at same level. It shows that when the thickness of the electronic functional layer satisfies the uniform conductance anisotropy everywhere, the influence of the thickness change on the luminescence uniformity is small. However, the increase of the thickness of the electronic functional layer may have a certain negative impact on the EQE and the lifespan of the device.

The photoelectric device and preparation method therefor, and display apparatus provided by embodiments of the present disclosure are described in detail above, and specific examples have been applied herein to illustrate principles and implement measures. The foregoing description of embodiments is provided merely to assist in understanding the present disclosure. For those skilled in the art, variations will be made in specific implementation and application scope in accordance with the teachings of the present disclosure. In view of the foregoing, the contents of this specification should not be construed as limiting the application.

1. A photoelectric device comprising an anode, a light-emitting layer, an electronic function layer, and a cathode disposed in stack;
wherein a material of the electronic function layer comprises a two-dimensional montmorillonite nanosheet.

2. The photoelectric device according to claim 1, the material of the electronic function layer is the two-dimensional montmorillonite nanosheet.

3. The photoelectric device according to claim 1, wherein the two-dimensional montmorillonite nanosheet is selected from one or more of a calcium-based two-dimensional montmorillonite nanosheet, a sodium-based two-dimensional montmorillonite nanosheet, a sodium-calcium-based two-dimensional montmorillonite nanosheet, and a magnesium-based two-dimensional montmorillonite nanosheet.

4. The photoelectric device according to claim 1, wherein the two-dimensional montmorillonite nanosheet is obtained by an inorganic modification or an organic modification;
wherein the inorganic modification comprises using one or more of an inorganic acid and an inorganic salt to modify; the organic modification comprises using one or more of an organic acid, a surfactant, a polymer monomer, and a coupling agent to modify.

5. The photoelectric device according to claim 4, wherein
the inorganic acid is selected from one or more of sulfuric acid, hydrochloric acid, nitric acid, and phosphoric acid;
the organic acid is selected from one or more of a carboxylic acid, a sulfonic acid, a sulfinic acid, and a thiocarboxylic acid;
the inorganic salt is selected from one or more of a halogen salt, a nitrate, a sulfate, a phosphate, a carboxylate, a sulfonate, a sulfinate, and a thiocarboxylate salt including aluminum, magnesium, zinc, copper, or sodium;
the surfactant is selected from one or more of a cationic surfactant, an anionic surfactant, and a nonionic surfactant;
the polymer monomer is selected from one or more of methyl methacrylate, N-vinyl pyrrolidone, pyrrole, ethylene terephthalate, and ethylene naphthalate;
the coupling agent is selected from one or more of a silane coupling agent, a titanate coupling agent, and a polyurethane coupling agent.

6. The photoelectric device according to claim 1, wherein the material of the electronic function layer comprises a composite of the two-dimensional montmorillonite nanosheet and a polymer; the polymer is selected from one or more of polymethyl methacrylate, polyimide, polyamide-imide, and polyethylene.

7. The photoelectric device according to claim 6, wherein, in the composite, a mass ratio of the polymer to the two-dimensional montmorillonite nanosheet is greater than 0:1 and less than or equal to 5:1.

8. The photoelectric device according to claim 1, wherein the anode is selected from one or more of a metal electrode, a silicon carbon electrode, a doped or non-doped metal oxide electrode, and a composite electrode; wherein a material of the metal electrode is selected from one or more of Al, Ag, Cu, Mo, Au, Ba, and Ca; a material of the silicon carbon electrode is selected from one or more of silicon, graphite, carbon nanotube, graphene and carbon fiber; a material of the doped or non-doped metal oxide electrode is selected from one or more of AZO, GZO, IZO, and AMO; a material of the composite electrode is selected from one or more of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, TiO₂/Ag/TiO₂, and TiO₂/Al/TiO₂;
the cathode is selected from one or more of a metal electrode, a silicon carbon electrode, a doped or non-doped metal oxide electrode, and a composite electrode; wherein a material of the metal electrode is selected from one or more of Al, Ag, Cu, Mo, Au, Ba, and Ca; a material of the silicon carbon electrode is selected from one or more of silicon, graphite, carbon nanotube, graphene and carbon fiber; a material of the doped or non-doped metal oxide electrode is selected from one or more of ITO, FTO, ATO, AZO, GZO, IZO, MZO, and AMO; a material of the composite electrode is selected from one or more of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, TiO₂/Ag/TiO₂, and TiO₂/Al/TiO₂;
a material of the light-emitting layer is selected from one or more of a quantum dot with single structure, a quantum dot with a core-shell structure, and a perovskite semiconductor material; the single structure quantum dot is selected from one or more of a group II-VI compound, a group IV-VI compound, a group III-V compound, a group I-III-VI compound; the group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe; the group IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe; the group III-V compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb; the group I-III-VI compound is selected from one or more of CuInS₂, CuInSe₂, and AgInS₂; a core of the quantum dot with a core-shell structure is selected from any one of the single structure quantum dots; a shell material of the quantum dot with a core-shell structure is selected from one or more of CdS, CdTe, CdSeTe, CdZnSe, CdZnS, CdSeS, ZnSe, ZnSeS, and ZnS; the perovskite semiconductor material is selected from a doped or non-doped inorganic perovskite type semiconductor, an organic perovskite semiconductor or an organic-inorganic hybrid perovskite type semiconductor; the inorganic perovskite type semiconductor has a general structural formula of AMX₃, wherein A is Cs⁺, and M is a divalent metal cation which is selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, and X is a halogen anion which is selected from one or more of Cl⁻, Br⁻, and I⁻; the organic-inorganic hybrid perovskite type semiconductor has a general structural formula of CMX₃, wherein C is a formamidyl, and M is a divalent metal cation which is selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, and X is a halogen anion which is selected from one or more of Cl⁻, Br⁻, and I⁻; the organic-inorganic hybrid perovskite type semiconductor has a general structural formula of BMX₃, wherein B is an Organic amine cation which is selected from one or more of CH₃(CH₂)ₙ₋₂NH₃⁺ or [NH₃(CH₂)ₙNH₃]²⁺, wherein n≥2, and M is a divalent metal cation which is selected from one or more of Pb²⁺, Sn²⁺, Cu²⁺, Ni²⁺, Cd²⁺, Cr²⁺, Mn²⁺ Co²⁺, Fe²⁺, Ge²⁺, Yb²⁺, and Eu²⁺, and X is a halogen anion which is selected from one or more of Cl⁻, Br⁻, and I.

9. The photoelectric device according to claim 1, wherein the photoelectric device further comprises a hole transport layer disposed between the anode and the light-emitting layer; the photoelectric device further comprises a hole injection layer disposed on a surface of the anode facing one side of the cathode; the photoelectric device further comprises an electron transport layer disposed between the light-emitting layer and the cathode; the photoelectric device further comprises an electron injection layer disposed on a surface of the cathode facing one side of the

10. The photoelectric device according to claim 1, wherein a thickness of the electronic functional layer is 1 nm to 50 nm.

11. A preparation method for a photoelectric device comprising:
providing a first electrode;
forming a light-emitting layer on the first electrode;
forming a second electrode on the light-emitting layer;
the method further comprises: obtaining an electronic functional layer by using a solution including the two-dimensional montmorillonite nanosheet with a solution method, wherein the electronic functional layer and the light-emitting layer are disposed between the first electrode and the second electrode.

12. The preparation method according to claim 11, wherein the first electrode is an anode, and the second electrode is a cathode, and prior to forming the second electrode, the obtaining an electronic functional layer by using a solution including the two-dimensional montmorillonite nanosheet with a solution method comprises disposing the solution including the two-dimensional montmorillonite nanosheet on the light-emitting layer by the solution method.

13. The preparation method according to claim 12, wherein the forming a light-emitting layer on the first electrode comprises forming a hole injection layer, the hole transport layer, and the light emitting layer successively on the anode, and the forming a second electrode on the light-emitting layer comprises forming an electron transport layer and the cathode successively on the electronic function layer.

14. The preparation method according to claim 11, wherein the first electrode is a cathode, and the second electrode is an anode, and prior to forming the light-emitting layer, the obtaining an electronic functional layer by using a solution including the two-dimensional montmorillonite nanosheet with a solution method comprises disposing the solution including the two-dimensional montmorillonite nanosheet on the first electrode by the solution method.

15. The preparation method according to claim 14, wherein the preparation method comprises:
providing a substrate, and forming the cathode on the substrate;
forming the electron transport layer on the cathode, and the electronic functional layer is formed on the electron transport layer;
sequentially forming the light emitting layer, the hole transport layer, the hole injection layer, and the anode on the electronic functional layer.

16. The preparation method according to claim 11, the two-dimensional montmorillonite nanosheet is obtained by an inorganic modification or an organic modification;
wherein the inorganic modification comprises using one or more of an inorganic acid and an inorganic salt to modify; the organic modification comprises using one or more of an organic acid, a surfactant, a polymer monomer, and a coupling agent to modify.

17. The preparation method according to claim 11, the solution including the two-dimensional montmorillonite nanosheet is a solution including a composite of the two-dimensional montmorillonite nanosheet and a polymer, and the polymer is selected from one or more of polymethyl methacrylate, polyimide, polyamide-imide, and polyethylene.

18. The preparation method according to claim 17, wherein, in the composite, a mass ratio of the polymer to the two-dimensional montmorillonite nanosheet is greater than 0:1 and less than or equal to 5:1.

19. The preparation method according to claim 11, wherein the first electrode is selected from one or more of a metal electrode, a silicon carbon electrode, a doped or non-doped metal oxide electrode, and a composite electrode; wherein a material of the metal electrode is selected from one or more of Al, Ag, Cu, Mo, Au, Ba, and Ca; a material of the silicon carbon electrode is selected from one or more of silicon, graphite, carbon nanotube, graphene and carbon fiber; a material of the doped or non-doped metal oxide electrode is selected from one or more of AZO, GZO, IZO, and AMO; a material of the composite electrode is selected from one or more of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, TiO₂/Ag/TiO₂, and TiO₂/Al/TiO₂;
the second electrode is selected from one or more of a metal electrode, a silicon carbon electrode, a doped or non-doped metal oxide electrode, and a composite electrode; wherein a material of the metal electrode is selected from one or more of Al, Ag, Cu, Mo, Au, Ba, and Ca; a material of the silicon carbon electrode is selected from one or more of silicon, graphite, carbon nanotube, graphene and carbon fiber; a material of the doped or non-doped metal oxide electrode is selected from one or more of ITO, FTO, ATO, AZO, GZO, IZO, MZO, and AMO; a material of the composite electrode is selected from one or more of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, TiO₂/Ag/TiO₂, and TiO₂/Al/TiO₂;
a material of the light-emitting layer is selected from one or more of a quantum dot with single structure, a quantum dot with a core-shell structure, and a perovskite semiconductor material; the single structure quantum dot is selected from one or more of a group II-VI compound, a group IV-VI compound, a group III-V compound, a group I-III-VI compound; the group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe; the group IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe; the group III-V compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb; the group I-III-VI compound is selected from one or more of CuInS₂, CuInSe₂, and AgInS₂; a core of the quantum dot with a core-shell structure is selected from any one of the single structure quantum dots; a shell material of the quantum dot with a core-shell structure is selected from one or more of CdS, CdTe, CdSeTe, CdZnSe, CdZnS, CdSeS, ZnSe, ZnSeS, and ZnS; the perovskite semiconductor material is selected from a doped or non-doped inorganic perovskite type semiconductor, an organic perovskite semiconductor or an organic-inorganic hybrid perovskite type semiconductor; the inorganic perovskite type semiconductor has a general structural formula of AMX₃, wherein A is Cs⁺, M is a divalent metal cation which is selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, X is a halogen anion which is selected from one or more of Cl⁻, Br⁻, and I⁻; the organic-inorganic hybrid perovskite type semiconductor has a general structural formula of CMX₃, wherein C is a formamidyl, M is a divalent metal cation which is selected from one or more of Pb²⁺, Sn²⁺, Cu²⁺, Ni²⁺, Cd²⁺, Cr²⁺ Mn²⁺, Co²⁺, Fe²⁺, Ge²⁺, Yb²⁺, and Eu²⁺, X is a halogen anion which is selected from one or more of Cl⁻, Br⁻, and I⁻; the organic-inorganic hybrid perovskite type semiconductor has a general structural formula of BMX₃, wherein B is a Organic amine cation which is selected from one or more of CH₃(CH₂)ₙ₋₂NH₃⁺ or [NH₃(CH₂)ₙNH₃]²⁺, wherein n≥2, M is a divalent metal cation which is selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, X is a halogen anion which is selected from one or more of Cl⁻, Br⁻, and I.

20. A display apparatus comprising a photoelectric device, wherein the photoelectric device comprises an anode, a light-emitting layer, an electronic function layer, and a cathode disposed in stack:
wherein a material of the electronic function layer comprises a two-dimensional montmorillonite nanosheet.
